(19) United States
(12) Patent Application Publication
(10) Pub. No.: US 2014/0326178 A1
(43) Pub. Date: Nov. 6, 2014

(54) ELECTROMAGNETIC VAPOR DEPOSITION APPARATUS

(71) Applicant: EverDisplay Optronics (Shanghai) Limited, Shanghai (CN)

(72) Inventors: ChiaChen LI, Shanghai (CN); TeinWang HUANG, Shanghai (CN)

(73) Assignee: EverDisplay Optronics (Shanghai) Limited, Shanghai (CN)

(21) Appl. No.: 14/267,626

(22) Filed: May 1, 2014

(30) Foreign Application Priority Data
May 2, 2013 (CN) 201310159305.2

(51) Int. Cl. H01L 51/56

(52) U.S. Cl. CPC H01L 51/56
USPC 118/663; 118/696

(57) ABSTRACT

The present disclosure discloses an electromagnetic vapor deposition apparatus comprising a plurality of electromagnets which form a plurality of electromagnetic regions when electronic current passes through. A programmable control equipment is electronically connected to each magnet unit to control magnetic polarity and magnetic intensity of each magnet unit. The programmable control equipment can adjust the magnetic intensity of each of the plurality of electromagnetic regions to adsorb the metal mask tightly. Meanwhile, the problem of colors mixing is overcome.

### CROSS-REFERENCE TO RELATED APPLICATIONS

The present application claims priority to and the benefit of Chinese Patent Application No. CN 201310159305.2, filed on May 2, 2013, the entire content of which is incorporated herein by reference.

### BACKGROUND OF THE INVENTION

1. Field of the Invention

The present disclosure relates to a deposition apparatus for producing OLED, more specifically, to an electromagnetic vapor deposition apparatus.

2. Description of the Related Art

OLED, i.e., Organic Light-Emitting Diode, is also known as Organic Electroluminescence Display. OLED, which adopting a very thin organic material layer and a rigid substrate process, has a self luminescent property, i.e., when electric current passes through, the organic material emits light. As the OLED display screen with a broad viewing angle and significantly energy economization, the OLED has been widely used. As the demand for OLED is increasing, the requirement of OLED technology is also more and more high. Among the OLED technologies, film forming technology for packaging is a very important and key technology, which directly affects the quality of the OLED products and the manufacturing cost. Presently, vapor deposition method to coating film is generally adopted in the related art.

FIG. 1 shows a top view of a thermal vapor deposition apparatus in the related art. As shown in FIG. 1, there are a plurality of permanent magnets placed, horizontally or vertically, on the holding frame, forming horizontal or vertical first permanent magnetic section S1, second permanent magnetic section S2, third permanent magnetic section S3, fourth permanent magnetic section S4, fifth permanent magnetic section S5 and sixth permanent magnetic section S6. In this case, the vapor deposition process is performed by the permanent magnet adsorbing the metal mask.

FIG. 2 shows a side view of the thermal vapor deposition apparatus in the related art. As shown in FIG. 2, Reaction Chamber 4 is provided with an Evaporation Source 5, wherein, above the Evaporation Source 5, from bottom to top, a Metal Mask 3, a Rigid Substrate 2 and a Holding Frame 1 are set up respectively. The Holding Frame 1 is provided with horizontal or vertical placement of multiple permanent magnets. The multiple permanent magnets form horizontal or vertical first permanent magnetic Section S1, second magnetic permanent Section S2, third permanent magnetic Section S3, fourth permanent magnetic Section S4, fifth permanent magnetic section S5 and sixth permanent magnetic Section S6, each of which is arranged horizontally or vertically.

Referring to the combination of the structures shown in FIG. 1 and FIG. 2, from which it can be seen that, when the deposition process is carried out, organic gas source is sprayed out from Evaporation Source 5 onto the surface of the rigid substrate to form a film. However, along with the vapor deposition process, organic particles easily deposit on Metal Mask 3. As Metal Mask 3 is fixed by a dragnet machine to the lower surface of Rigid Substrate 2, its tension area varies with the distance from the center of the metal mask, specifically, the position is closer from the center of the metal mask, and the tension is weaker. Meanwhile, the tension of Metal Mask 3 can not be controlled by the permanent magnet to adjust its magnetic intensity of each magnet area, therefore, the center of the Metal Mask 3 prone to sagging, as shown in FIG. 2, resulting in that Metal Mask 3 can not close to the Rigid Substrate 2 tightly. Therefore, during the deposition process, colors mingling will easily occur, which affects the yield thereof.

### SUMMARY OF THE INVENTION

An embodiment of the present disclosure is directed toward an electromagnetic vapor deposition apparatus capable of overcoming the problem of colors mixing.

The electromagnetic vapor deposition apparatus, comprising: a holding frame; a plurality of electromagnet units located on the holding frame; and a programmable control equipment electronically connected to each of the plurality of electromagnet units for controlling the magnetic polarity and magnetic intensity of each of the plurality of electromagnet units.

According to one embodiment of the present disclosure, further comprising an evaporation source for forming films arranged below a rigid substrate.

According to one embodiment of the present disclosure, further comprising a metal mask;

wherein, the holding frame is located above the evaporation source fixedly; and the holding frame adsorbs the metal mask to fix the rigid substrate between the metal mask and the holding frame.

According to one embodiment of the present disclosure, wherein the programmable control equipment controls the polarity of the plurality of electromagnet units to form a plurality of electromagnetic regions, and the plurality of electromagnetic regions form a back-shape array matrix, wherein one of the plurality of electromagnetic regions region is at the innermost position, around which the other of the plurality of electromagnetic regions are arranged one to another.

According to one embodiment of the present disclosure, wherein the polarity of one of the plurality of electromagnetic regions is opposite to the adjacent electromagnetic regions in the back-shape array matrix.

According to one embodiment of the present disclosure, wherein a magnetic sensor is provided above each of the plurality of electromagnetic regions.

According to one embodiment of the present disclosure, wherein the magnetic sensor is connected to the programmable control equipment to transmit the magnetic intensity of each of the plurality of electromagnetic regions to the programmable control equipment.

According to one embodiment of the present disclosure, wherein the magnetic sensor converts the magnetic intensity of the electromagnetic regions into electronic signal and transmits the signal to the programmable control equipment.

### BRIEF DESCRIPTIONS OF THE DRAWINGS

The accompanying drawings, together with the specification, illustrate exemplary embodiments of the present disclosure, and, together with the description, serve to explain the principles of the present disclosure.

FIG. 1 shows a top view of a thermal vapor deposition apparatus in the related art;

FIG. 2 shows a side view of the thermal vapor deposition apparatus in the related art;

FIG. 3 shows a top view of the electromagnetic vapor deposition apparatus of the present disclosure;

FIG. 4 shows a side view of the electromagnetic vapor deposition apparatus of the present disclosure;

FIG. 5 shows a partial side view of the electromagnetic vapor deposition apparatus of the present disclosure.

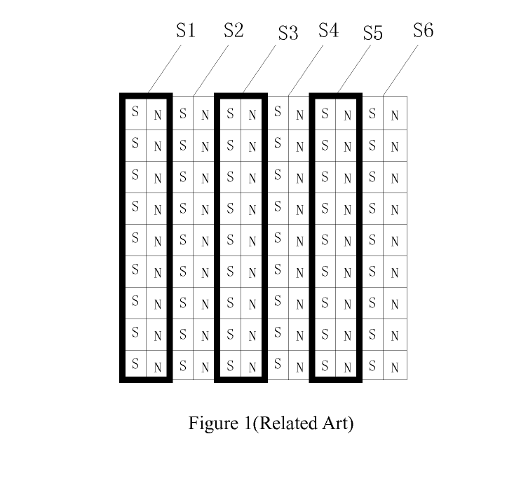

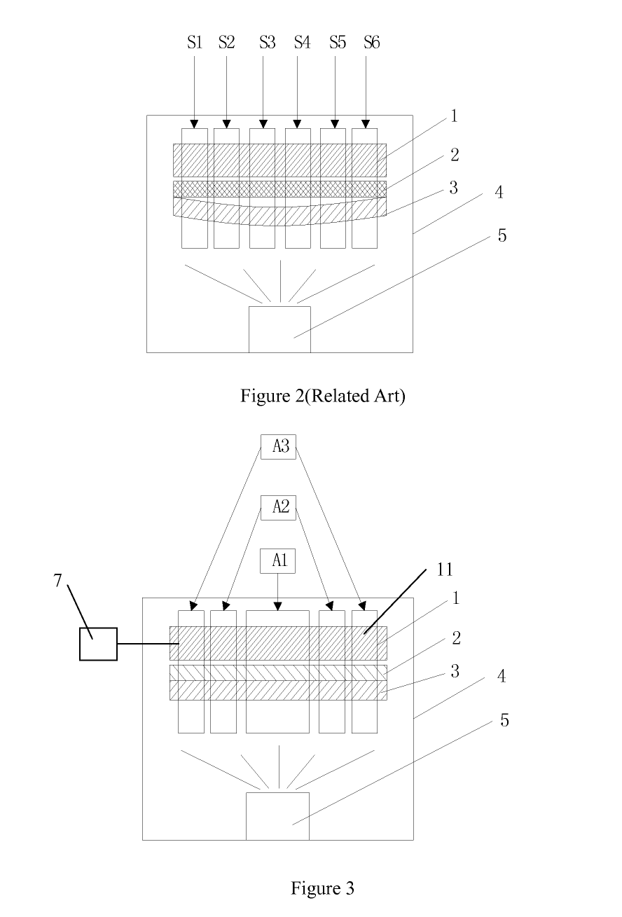

### DETAILED DESCRIPTIONS

The present disclosure will now be described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used herein, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

As used herein, “around”, “about” or “approximately” shall generally mean within 20 percent, preferably within 10 percent, and more preferably within 5 percent of a given value or range. Numerical quantities given herein are approximate, meaning that the term “around”, “about” or “approximately” can be inferred if not expressly stated.

As used herein, the term “plurality” means a number greater than one.

### Embodiment 1

FIG. 3 shows the top view of the electromagnetic vapor deposition apparatus of the present disclosure, as shown in FIG. 3, the coating controlling device comprises Main Reaction Chamber 4. Evaporation Source 5 for forming films is provided at the bottom of Main Reaction Chamber 4. Above Evaporation Source 5, form bottom to top, Metal Mask 3, Rigid Substrate 2 and Holding Frame 1 are placed in sequence. Preferably, Rigid Substrate 2 is a glass substrate.

Evaporation Source 5 sprays organic gas upward to the surface of Rigid Substrate 2 to depositing a film.

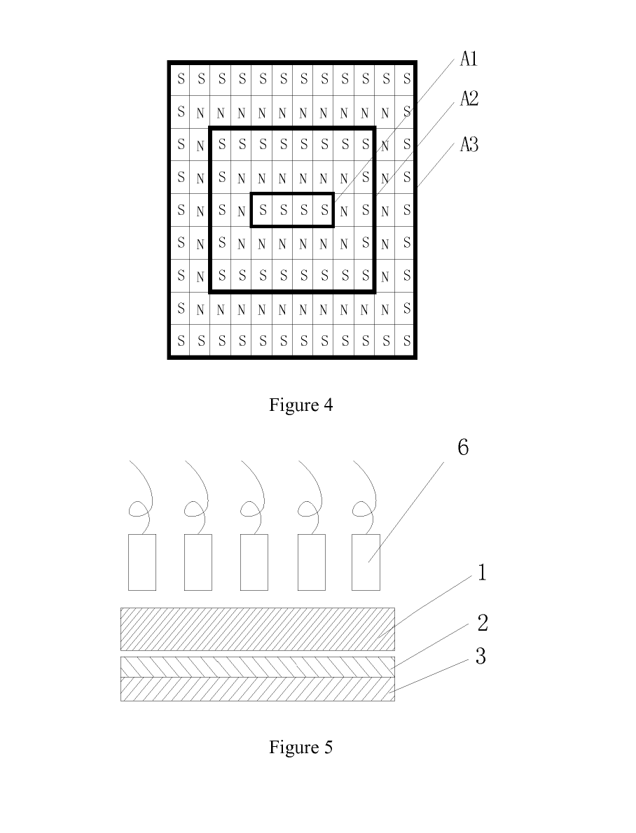

FIG. 4 shows a side view of the electromagnetic vapor deposition apparatus of the present disclosure. As shown in FIG. 4, Holding Frame 1 is provided with a plurality of Electromagnet Units 11 to adsorb Metal Mask 3 onto the lower surface of Rigid Substrate 2. When electronic current passes through, the plurality of Electromagnet Units 11, which are arranged on Holding Frame 1, will form a plurality of electromagnetic regions, such as a First Electromagnetic Region A1, a Second Electromagnetic Region A2, a Third Electromagnetic Region A3, . . . , and a Nth Magnetic Region. These electromagnetic regions together form a back-shaped array matrix, i.e., as shown in FIG. 4, Second Electromagnetic Region A2 rounds First Electromagnetic Region A1; Third Electromagnetic Region A3 rounds Second Electromagnetic Region A2, and so on, Nth Electromagnetic Region rounds (N−1)th Electromagnetic Region.

Further preferably, the magnetic polarity of one of the plurality of electromagnetic regions is opposite to the adjacent electromagnetic regions, for example, if (N+1)th Electromagnetic Region is N pole, then (N+2)th Electromagnetic Region and Nth Electromagnetic Region should be S pole. The number of the plurality of electromagnetic regions and the area of each of the plurality of electromagnetic regions can be adjusted according to the dimensions of Metal Mask 3. Specifically, if the area of Metal Mask 3 is large, the area and/or numbers of the plurality of electromagnetic regions will be increased; however, if the area of Metal Mask 3 is small, then the area and/or numbers of the plurality of electromagnetic regions will be decreased, so that Metal Mask 3 can be adsorbed onto Rigid Substrate 2 by the electromagnets more effectively.

### Embodiment 2

The electromagnetic vapor deposition apparatus further comprises a Programmable Control Equipment 7 and sensors. Programmable Control Equipment 7 is electrically connected to each of the plurality of Electromagnet Units 11 to control the magnetic polarity and magnetic intensity of each of the plurality of Electromagnet Units 11. Meanwhile, the sensors can be electrically connected to Programmable Control Equipment 7, such as Programmable Logic Controller Programmable Control Equipment (“PLC”, hereinafter).

As shown in FIG. 5, which shows a partial side view of the electromagnetic vapor deposition apparatus of the present disclosure, Rigid Substrate 2 is provided between Metal Mask 3 and Holding Frame 1. Above each of the plurality of electromagnetic regions formed by the plurality of Electromagnetic Units 11 when electronic current passes through, a Sensor 6, such as a magnetic sensor, is provided for monitoring the magnetic intensity of each of the plurality of Electromagnetic Units 11 below the corresponding Sensor 6, and for converting the magnetic intensity into current signal to transmit the magnetic intensity to Programmable Control Equipment 7. When Programmable Control Equipment 7 receives the magnetic intensity signal sent by Sensor 6, according to the process parameters, such as magnetic intensity and deformation information of Metal Mask 3, Programmable Control Equipment 7 changes the electronic current intensity of each of the plurality of Electromagnetic Units 11 in each of the plurality of electromagnetic regions in real time. Therefore, the magnetic intensity of the corresponding electromagnetic region will be increased or decreased to adjust the adaption of Metal Mask 3 to Rigid Substrate 2, so that Metal Mask 3 will be more closely adsorbed onto Rigid Substrate 2. Consequently, the sagging phenomenon of Metal Mask 3 due to the deposition of too much organic material if the vapor deposition process is sustained for too long time. Therefore, the problem of colors mingling can be overcome.

By a dragnet machine, Metal Mask 3 is close to the surface of Rigid Substrate 2. Programmable Control Equipment 7 is operated to provide electronic current for each of the plurality of Electromagnet Units 11 in Holding Frame 1. When the electronic current passes through Electromagnet Units 11, Metal Mask 3 is adsorbed onto Rigid Substrate 2. Meanwhile, the organic gas is sprayed from Evaporation Source 5 at the bottom of the reaction chamber onto the surface of Rigid Substrate 2 to form a film, such as an organic film.

However, along with the vapor deposition process, the organic material will deposit on Metal Mask 3 increasingly. Too much organic material deposition will lead to the sagging tendency of Metal Mask 3, which can be determined according to the deformation of Metal Mask 3. According to the detected magnetic intensity by the sensor, Programmable Control Equipment 7 adjusts the electronic current intensity of the corresponding Electromagnet Unit 11 where Metal Mask 3 sags, to increase the magnetic intensity of the electromagnetic region. Because the adsorption force to the sagging position of Metal Mask 3 is enhanced to adsorb Metal Mask 3 more tightly onto the surface of Rigid Substrate 2. Consequently, the sagging can be avoided. Therefore, during the vapor deposition process, the problem of colors mixing is prevented.

Meanwhile, above each of the plurality of electromagnetic regions, a Magnetic Sensor 6 is provided to detect the magnetic intensity of each of the plurality of electromagnetic regions below it and to convert the magnetic intensity into electronic signal transformed to Programmable Control Equipment 7. The operator can obtain the magnetic intensity of each of the plurality of electromagnetic regions, in order to adjust the process parameters of each of the plurality of electromagnetic regions in real-time if necessary, i.e., adjust the electronic current intensity of each of the plurality of electromagnetic regions by Programmable Control Equipment 7 according to the received electronic signal corresponding to the magnetic intensity. Consequently, the operator can control the magnetic intensity of each of the plurality of electromagnetic regions. The purpose is absorbing Metal Mask 3 onto the surface of Rigid Substrate 2 tightly and meanwhile preventing strong magnetic intensity to adsorb Metal Mask 3 onto Rigid Substrate too tightly to damage the product.

While the present disclosure has been described in connection with certain exemplary embodiments, it is to be understood that the invention is not limited to the disclosed embodiments, but, on the contrary, is intended to cover various modifications and equivalent arrangements included within the spirit and scope of the appended claims, and equivalents thereof.

What is claimed is:

1. An electromagnetic vapor deposition apparatus, comprising:
a holding frame;
a plurality of electromagnet units located on the holding frame; and
a programmable control equipment electronically connected to each of the plurality of electromagnet units for controlling the magnetic polarity and magnetic intensity of each of the plurality of electromagnet units.

2. The electromagnetic vapor deposition apparatus as claimed in claim 1, further comprising an evaporation source for forming films arranged below a rigid substrate.

3. The electromagnetic vapor deposition apparatus as claimed in claim 2, further comprising a metal mask;
wherein, the holding frame is located above the evaporation source fixedly; and the holding frame adsorbs the metal mask to fix the rigid substrate between the metal mask and the holding frame.

4. The electromagnetic vapor deposition apparatus as claimed in claim 1, wherein the programmable control equipment controls the polarity of the electromagnet units to form a plurality of electromagnetic regions; and the plurality of electromagnetic regions form a back-shape array matrix, wherein one of the plurality of electromagnetic regions is at the innermost position, around which the other of the plurality of electromagnetic regions are arranged one to another.

5. The electromagnetic vapor deposition apparatus as claimed in claim 4, wherein the polarity of one of the plurality of electromagnetic regions is opposite to the adjacent electromagnetic regions in the back-shape array matrix.

6. The electromagnetic vapor deposition apparatus as claimed in claim 4, wherein a magnetic sensor is provided above each of the plurality of electromagnetic regions.

7. The electromagnetic vapor deposition apparatus as claimed in claim 6, wherein the magnetic sensor is connected to the programmable control equipment to transmit the magnetic intensity of each of the plurality of electromagnetic regions to the programmable control equipment.

8. The electromagnetic vapor deposition apparatus as claimed in claim 7, wherein the magnetic sensor converts the magnetic intensity of the electromagnetic regions into electronic signal and transmits the signal to the programmable control equipment.
